(19) United States
(12) Patent Application Publication
(10) Pub. No.: US 2025/0149483 A1
(43) Pub. Date: May 8, 2025

(54) INTEGRATED DEVICE PACKAGES WITH INTEGRATED DEVICE DIE AND DUMMY ELEMENT

(71) Applicant: ADEIA SEMICONDUCTOR BONDING TECHNOLOGIES INC., San Jose, CA (US)

(72) Inventor: Belgacem Haba, Saratoga, CA (US)

(21) Appl. No.: 18/770,099

(22) Filed: Jul. 11, 2024

Related U.S. Application Data
(63) Continuation of application No. 18/295,776, filed on Apr. 4, 2023, now Pat. No. 12,046,569.
Application No. 18/295,776 is a continuation of application No. 16/917,686, filed on Jun. 30, 2020, now Pat. No. 11,631,647.

(51) Int. Cl. H01L 23/00; H01L 21/56; H01L 21/78

(52) U.S. Cl. CPC H01L 24/08; H01L 21/561; H01L 21/565; H01L 21/568; H01L 21/78; H01L 24/80; H01L 2224/08145; H01L 2224/80006; H01L 2224/80895; H01L 2224/80896

(57) ABSTRACT

In one embodiment, an integrated device package is disclosed. The integrated device package can comprise a carrier an a molding compound over a portion of an upper surface of the carrier. The integrated device package can comprise an integrated device die mounted to the carrier and at least partially embedded in the molding compound, the integrated device die comprising active circuitry. The integrated device package can comprise a stress compensation element mounted to the carrier and at least partially embedded in the molding compound, the stress compensation element spaced apart from the integrated device die, the stress compensation element comprising a dummy stress compensation element devoid of active circuitry. At least one of the stress compensation element and the integrated device die can be directly bonded to the carrier without an adhesive.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The field relates to integrated device packages and methods for forming the same.

### Description of the Related Art

In various packaging arrangements, it can be advantageous to arrange multiple integrated device dies within a package, e.g., system-in-package (SIPs). For example, some packages include different types of active chips or integrated device dies spaced apart from one another along a package substrate. In addition, three-dimensional (3D) integration techniques often utilize packages in which two or more integrated device dies are stacked on top of and electrically connected to one another. A molding compound or encapsulant can be provided over the integrated device dies, which can generate stresses in the package. Accordingly, there remains a continuing need for improved integrated device packages.

### BRIEF DESCRIPTION OF THE DRAWINGS

These aspects and others will be apparent from the following description of preferred embodiments and the accompanying drawing, which is meant to illustrate and not to limit the invention, wherein:

FIGS. 1A-1C schematically illustrates the use of a sacrificial carrier in various direct bonding processes.

FIG. 2 illustrates a plurality of elements directly bonded to a carrier.

FIGS. 3A-3C show various examples in which elements are directly bonded to a carrier without an adhesive.

FIG. 4A is a schematic side view of a plurality of elements directly bonded to a carrier and with a protective material applied over the elements and within gaps between the elements.

FIG. 4B is a schematic side view of a plurality of elements that include one or more dummy elements directly bonded to a carrier.

FIGS. 5A-5C illustrate a series of processing steps for forming a reconstituted wafer.

FIG. 6 is a schematic side sectional view of a reconstituted wafer having a bonding layer configured to directly bond to another reconstituted wafer or substrate.

FIG. 7A illustrates two opposing reconstituted wafers prior to direct bonding.

FIG. 7B illustrates the two opposing reconstituted wafers after being directly bonded to one another.

FIG. 8A-8B illustrate methods and structures for stacking more than two reconstituted wafers, according to various embodiments.

FIGS. 9A-9F illustrate various face up bonded structures, according to various embodiments.

FIGS. 10A-10E illustrate various face down bonded structures, according to various embodiments.

FIG. 11 illustrates another embodiment in which an additional filler material can serve as a second protective material and may be provided over a conformal protective material in the gaps between adjacent elements.

FIGS. 12A-12C illustrate a method for forming a reconstituted wafer according to various embodiments.

FIGS. 13A-13B illustrate a method for forming a reconstituted wafer according to various embodiments.

FIGS. 14A-14C illustrate another embodiment in which a mold compound can be provided between adjacent elements directly bonded to a carrier, and a metal can be provided on the mold compound.

FIGS. 15A-15C illustrate another embodiment in which a mold compound can be provided between adjacent elements directly bonded to a carrier, and a metal can be provided on both sides of the mold compound.

FIGS. 16A-16C illustrate another embodiment in which a protective coating or layer can be provided between the mold compound and the carrier.

FIGS. 17A-17D illustrates additional bonded structures that can be provided with the methods disclosed herein.

FIG. 18A is a schematic side sectional view of an integrated device package, according to another embodiment.

FIG. 18B is a schematic top plan view of the integrated device package of FIG. 18A, with the molding compound hidden for ease of illustration.

FIG. 18C is a schematic top plan view of an integrated device package that includes increased lateral overlap among stress compensation elements.

FIG. 19 is a schematic diagram of a system incorporating one or more bonded structures, according to various embodiments.

### DETAILED DESCRIPTION

Various embodiments disclosed herein relate to a bonded structure comprising a first element (e.g., a first integrated device die) having a first side and a second side opposite the first side. The bonded structure can include a second element (e.g., a second integrated device die) having a first side and a second side opposite the first side. The first side of the second integrated device die can be directly bonded to the first side of the first integrated device die without an intervening adhesive along a bonding interface. A protective material can be disposed about a periphery (e.g., respective sidewalls) of the first and second integrated device dies. The protective material can extend from the second side of the first integrated device die to the second side of the second integrated device die. In various embodiments, portions of the protective material can be disposed within gaps between adjacent first integrated device dies or elements. In some embodiments, the protective material can comprise an inorganic dielectric, such as silicon dioxide, silicon nitride, polysilicon, amorphous silicon, etc.

The embodiments disclosed herein can comprise wafer-level processes in which wafers or substrates, serving as carriers, are provided with a plurality of integrated device dies and a protective material (which can comprise one or a plurality of protective layers) over the integrated device dies. The die(s) and protective material can form at least a portion of a reconstituted wafer which can be bonded (e.g., directly bonded without an adhesive) to another reconstituted wafer formed by a similar process. The bonded reconstituted wafers can be singulated to form a plurality of bonded structures, for example after removal of the carriers. The bonded structures can comprise packaging structures in some embodiments. As used herein, direct bond interconnects, or DBI®, can comprise bonded structures in which densely dispersed conductive contacts are bonded to one another without an intervening adhesive. In various embodiments, the surrounding dielectric or nonconductive materials can also be directly bonded without an intervening adhesive. A ZiBond® process can comprise a direct bond between nonconductive materials without an intervening adhesive. Examples of DBI and ZiBond processes and structures may be found throughout at least U.S. Pat. Nos. 9,391,143; 10,141,218; 10,147,641; 9,431,368; and 7,126,212, the entire contents of each of which are incorporated by reference herein in their entireties and for all purposes. Each of the singulated dies mounted on the carriers can be tested prior to mounting, such that all dies in the reconstituted wafer can be Known Good Dies (KGD).

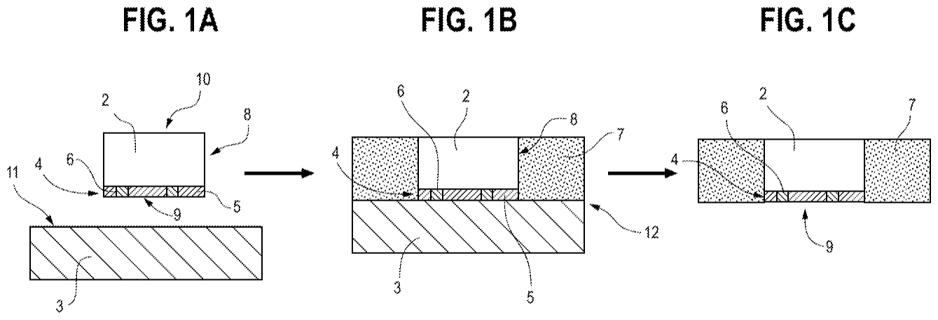

FIGS. 1A-1C schematically illustrate the use of a sacrificial carrier 3 in various direct bonding processes. As shown, in some embodiments, an element 2 can be directly bonded to a carrier 3 without an adhesive. Throughout this application, the element 2 (or any of the other elements described herein) can comprise any suitable type of element, such as a semiconductor element (e.g., an integrated device die), an optical element, etc. The carrier 3 can comprise any suitable type of carrier, such as a carrier with one or more logic or processing devices, and/or a sacrificial carrier (e.g., a carrier without active processing circuitry) that is to be removed at some point during processing.

The element 2 can comprise a front side 9 and a back side 10 opposite the front side 9. In various embodiments, the front side 9 can comprise a surface nearest to active circuitry or devices formed in the element 2. A first front bonding layer 4 can be provided at the front side 9 of the element 2. Although the bonding layer 4 is shown at the front side 9 of the element 2, a bonding layer may also or alternatively be provided on the back side 10 for bonding. The bonding layer 4 can comprise one or a plurality of contact pads 6 disposed within or surrounded by a nonconductive field region 5. In some embodiments, the contact pads can comprise copper, although other conductive materials are suitable. In some embodiments, the nonconductive field region can comprise a dielectric such as silicon oxide, silicon nitride, etc. The back side 10 may or may not include active circuitry or devices. In various embodiments, the element 2 can comprise a singulated element (such as a singulated device die) having a side surface 8. The side surface 8 can comprise markings indicative of a singulation process, for example, saw markings, etch patterns, etc.

As explained above, and as shown in FIG. 1A, the element 2 (e.g., a die) can be directly bonded to the carrier 3 without an intervening adhesive along a bond interface 12. The front bonding layer 4 can be prepared for bonding, as explained above. For example, the front bonding layer 4 can be polished to a very low surface roughness and processed so as to enhance dielectric-to-dielectric direct bonding. In some embodiments, the surfaces to be bonded may be terminated with a suitable species and activated prior to bonding. For example, in some embodiments, the surfaces to be bonded may be very lightly etched for activation and exposed to a nitrogen-containing solution and terminated with a nitrogen-containing species. As one example, the surfaces to be bonded may be exposed to an ammonia dip after a very slight etch, and/or a nitrogen-containing plasma (with or without a separate etch).

Once the surfaces are prepared, the nonconductive field region 5 of the element 2 can be brought into contact with corresponding nonconductive regions of the carrier 3. The interaction of the activated surfaces can cause the nonconductive region 5 of the element 2 to directly bond with the corresponding nonconductive regions of the carrier 3 without an intervening adhesive, without application of external pressure, without application of voltage, and at room temperature. In various embodiments, the bonding forces of the nonconductive regions can be covalent bonds that are greater than Van der Waals bonds. In some embodiments, only nonconductive field regions of the element 2 are directly bonded to corresponding nonconductive regions of the carrier 3. In other embodiments, however, contact pads 6 of the element 2 can be directly bonded to corresponding conductive contacts of the carrier 3, and the nonconductive region 5 can also be directly bonded to the nonconductive regions of the carrier 3. In such embodiments, direct bonding of the contacts can improve alignment of the element 2 relative to the carrier 3. In the embodiments disclosed herein, the use of direct bonding can reduce movement during assembly as compared to implementations that utilize an intervening adhesive.

As shown in FIG. 1B, a protective material 7 can be applied over at least a portion of the element 2, including about at least a periphery or side surface 8 of the element 2. In some embodiments, the protective material 7 can be deposited along the side surface 8 and over an upper surface of the carrier 3. The protective material 7 can comprise one or more protective layers, including one or more inorganic layers, such as silicon oxide, silicon nitride, polysilicon, amorphous silicon, a metal, etc.

As shown in FIG. 1C, the carrier 3 can be removed from the element 2 and the protective material 7 in any suitable manner. In the illustrated embodiment, the carrier 3 can comprise a silicon substrate or element with a nano oxide layer 11, which as used herein can include at least one of a native silicon oxide layer and a thermal silicon oxide layer. Each of the embodiments disclosed herein can utilize such a carrier with nano oxide layer 11. In some embodiments, in the carrier removal process the carrier 3 can be selectively etched using the silicon nano oxide layer 11 as an etch stop. In some embodiments, at least a portion of the nano oxide 11 layer can remain after removing the silicon base material of the carrier 3. In other embodiments, the entirety of the carrier 3 (e.g., the silicon base material and the nano oxide layer 11) can be removed. In embodiments that utilize a nano oxide layer 11, the element 2 can be planarized for bonding, but the carrier 3 may not be planarized prior to direct bonding. In other embodiments, both the element 2 and carrier 3 can be planarized for direct bonding. Direct bonding and subsequent removal of the carrier 3 as described herein can advantageously leave a planar surface for a reconstituted wafer for further processing as desired, including for additional direct bonding processes. In contrast, reconstituted wafers formed on sacrificial or temporary adhesive layers (e.g., tape or film) do not reliably provide planar surfaces and thus can lead to subsequent alignment issues, e.g., for subsequent direct bonding of dies for stacking. Such stacking with direct bonding could be by way of direct bonding individual second dies on a first reconstituted wafer, or simultaneously bonding multiple second dies in a second reconstituted wafer.

Beneficially, the embodiment of FIGS. 1A-1C can enable the reconstitution of wafers for direct bonding with improved alignment accuracy. For example, although only one element 2 or die is shown in FIGS. 1A-1C, it should be appreciated that an array of multiple dies can be provided, and as shown below. In other applications in which an adhesive is used to bond the elements 2 (e.g., dies) to the carrier 3, the elements 2 or dies may become misaligned relative to the carrier 3 due to movement or migration of the adhesive, for example, during or after heating or during placement for bonding. Such misalignments can result in misalignment for subsequently bonded structures and negatively affect the performance of the bonded structures. The embodiments disclosed herein can beneficially reduce misalignment by providing a direct bond interconnection with the carrier 3, which can serve to effectively fix the element 2 or die relative to the carrier 3 for subsequent processing, such as providing a protective material 7 (inorganic or organic) over the element 2, or any other suitable processing.

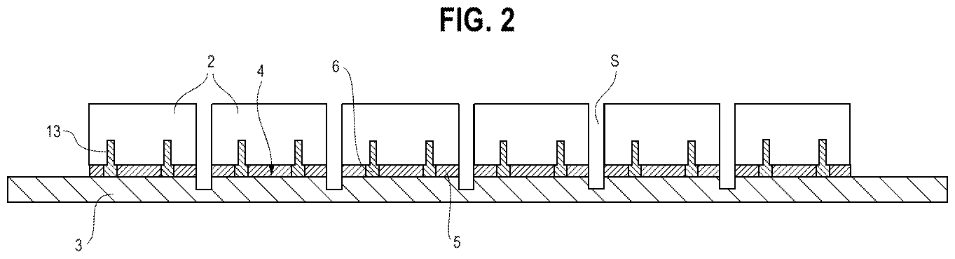

FIG. 2 illustrates a plurality of elements 2 directly bonded to a carrier 3, such as a wafer. Unless otherwise noted, reference numerals in FIG. 2 may represent components that are the same as or generally similar to like-numbered components of FIGS. 1A-1C. In FIG. 2, each element 2 can include one or more conductive vias 13 connected to back side(s) of corresponding contact pads 6. As shown in FIG. 2, the conductive vias may initially extend upwardly from the contact pad and terminate within the body of the element 2. After the directly bonding, the dies or elements 2 can be diced or singulated into a plurality of diced or singulated elements 2. As explained herein, the removal of a silicon substrate using the nano oxide layer 11 may leave a substantially smooth surface for subsequent direct bonding.

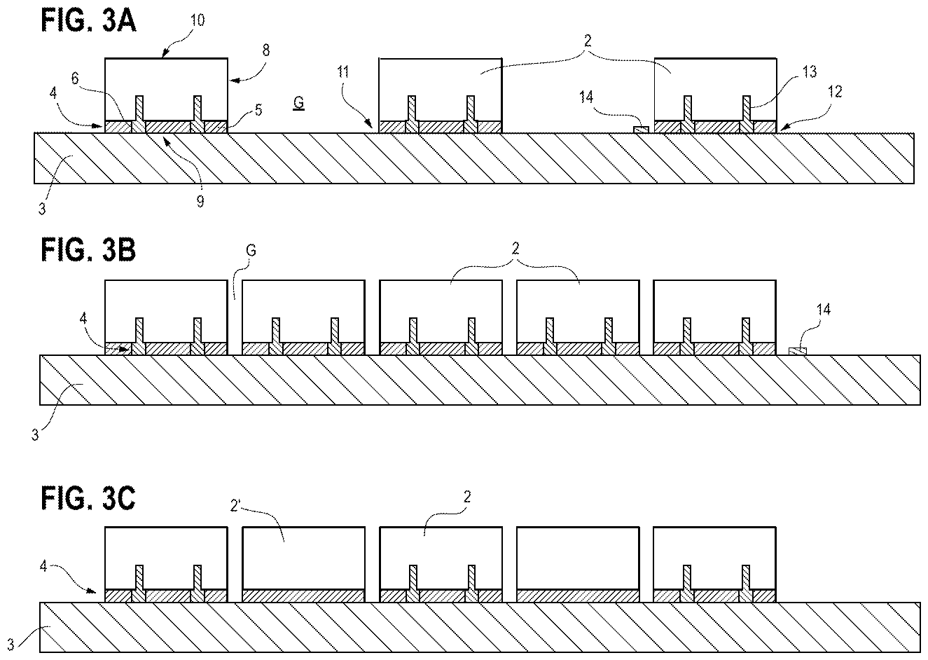

FIGS. 3A-3C show various examples in which elements 2 (e.g., integrated device dies) are directly bonded to a carrier 3 (e.g., a silicon substrate with nano oxide layer 11) without an intervening adhesive. FIG. 3A illustrates a relatively wide separation or gap G between elements 2, while FIG. 3B illustrates a relatively narrow separation or gap G between elements 2. FIG. 3C illustrates additional dummy elements 2′ or dies disposed between active elements 2 or dies, with relatively narrow gaps G therebetween. Providing the narrow gaps G in FIGS. 3B and 3C can beneficially reduce the amount of protective material 7 used to fill the gaps G in subsequent steps and can enable conformal filling of the gaps G. Further, as shown in FIGS. 3A and 3B, one or more alignment feature(s) 14 can be provide on the upper surface of the carrier 3. The alignment features 14 can be selectively positioned on the carrier 3 to assist in accurate placement of the elements 2.

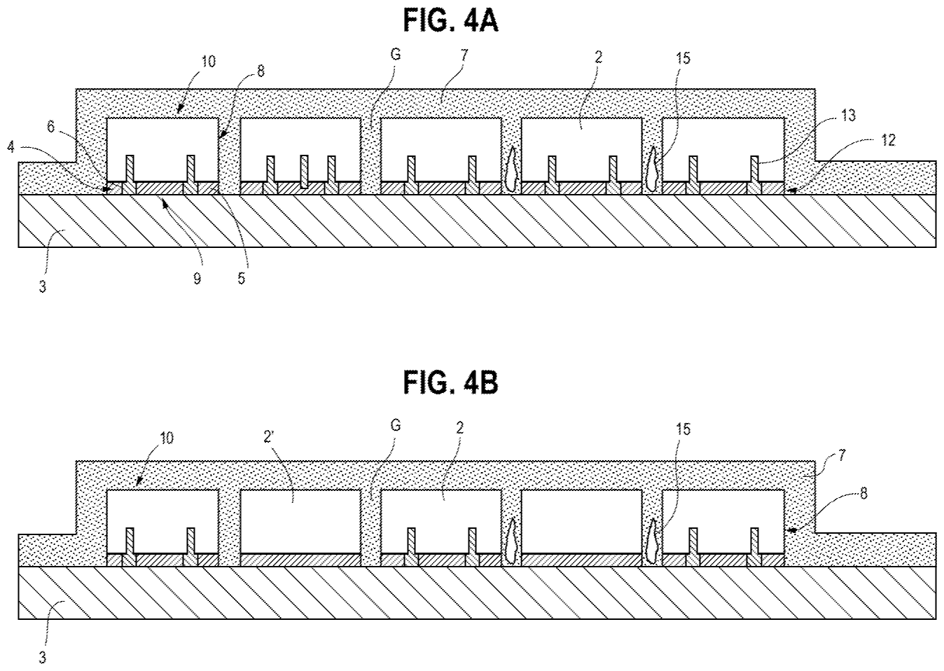

FIG. 4A is a schematic side view of a plurality of elements 2 directly bonded to a carrier 3 and with a protective material 7 applied over the elements 2 and within the gaps G between the elements 2. In FIG. 4A, the elements 2 are illustrated as being all active integrated device dies. In FIG. 4B, some of the elements comprise dummy elements 2′, such as inactive blocks of semiconductor material (e.g., silicon). In FIGS. 4A and 4B, a protective layer 7 (such as an inorganic protective layer) can be provided over portions of the elements 2, including around a portion of the periphery (e.g., the side surface 8) within the gaps G and over upper surfaces (which are the back sides 10 in FIGS. 4A-4B) of the elements 2. Scams 15 such as voids or discontinuities may be present in the protective material 7.

The protective layer 7 can include one or a plurality of protective layers, including, e.g., inorganic or organic protective layer(s). In the illustrated embodiment, for example, the protective layer 7 can comprise inorganic layer(s) such as silicon oxide, silicon nitride, polysilicon, amorphous silicon, or a metal. In other embodiments, at least a portion of the protective material 7 can comprise an organic material, such as a molding compound or epoxy. In some embodiments, the protective material 7 comprises both a conformal layer and a gap-fill layer. Beneficially, the protective material 7 can assist in affixing the elements 2 to the carrier 3 such that the elements 2 do not shift during subsequent direct bonding processes. The protective material 7 can also assist in protecting the elements 2 during polishing and other processing techniques to prevent damage to the dies (e.g., chipping). Examples of structures and processes for providing protective material 7 on and between adjacent directly bonded dies over a carrier, for use in conjunction with post-bonding thinning and/or singulation processes, are disclosed in U.S. Pat. No. 10,204,893, the entire contents of which are hereby incorporated by reference herein in their entirety and for all purposes.

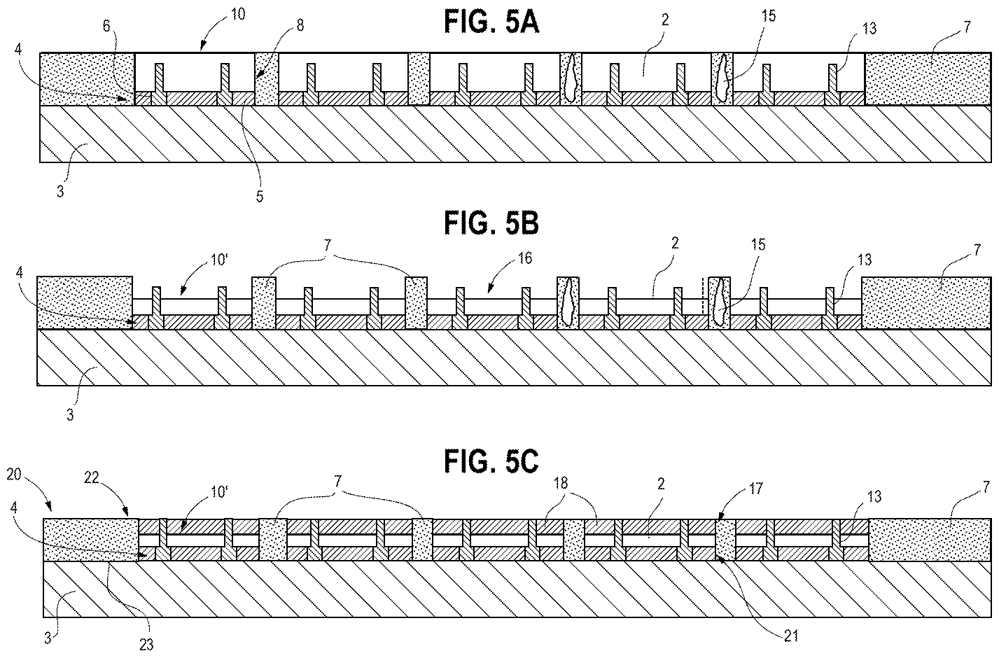

FIGS. 5A-5C illustrate a series of processing steps for forming a reconstituted wafer 20. The reconstituted wafer 20 can be bonded (e.g., directly bonded) to another reconstituted wafer 20 or to other substrates in subsequent steps. In FIG. 5A, the upper surfaces of the conformal protective material 7 can be removed, e.g., by etching, lapping, grinding, polishing, etc. In some embodiments, the removal of the protective material 7 can also remove a portion of the back side 10 of the elements 2. In other embodiments, the removal step can terminate at the back side 10 of the element 2.

Turning to FIG. 5B, a portion of the element 2 from the back side 10 can be removed by etching, lapping, chemical mechanical polishing (CMP), or any other suitable method, to form a thinned back side 10′ of the element 2. As shown in FIG. 5A, this removal step can expose the conductive through substrate vias (TSVs) 13 or other electrical interconnects formed within the elements. The removal step can also form a cavity 16 defined at least in part by the thinned back side 10′ of the element 2 and side walls of the protective material 7. In FIG. 5C, a nonconductive layer 18 (e.g., a second oxide layer) can be provided (e.g., deposited) over the thinned back sides 10′ of the elements 2 and around the exposed vias 13. In some embodiments, the provided nonconductive layer 18 (for example, silicon oxide) can be lapped or polished to generate a planar surface and to ensure that the nonconductive layer 18 is generally planar relative to the exposed ends of the vias 13 and the protective material.

In FIG. 5C, the reconstituted wafer 20 can comprise a front surface 22 configured to be bonded (e.g., direct bonded) to another reconstituted wafer or other type of substrate. The reconstituted wafer 20 can also comprise a back surface 23. In the reconstituted wafer 20 of FIG. 5C, the protective material 7 can be disposed between adjacent elements 2 and can extend from the front surface 22 of the reconstituted wafer 20 to the upper surface of the carrier 3. A vertical interface 19 can be defined between the nonconductive layer 18 over the element 2 and the protective material 7. Similarly, a vertical interface 21 can be defined between the bonding layer 4 and the protective material 7.

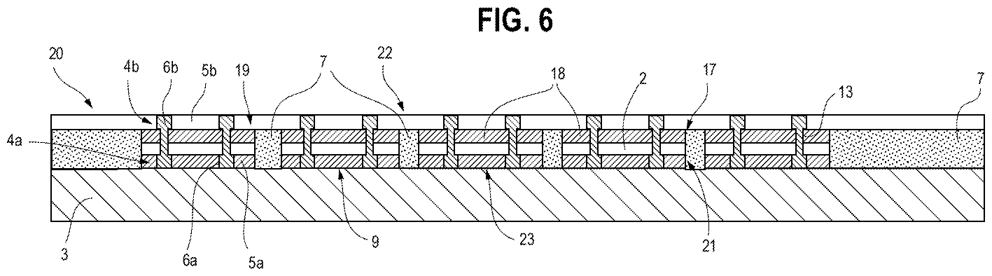

FIG. 6 is a schematic side sectional view of a reconstituted wafer having a second bonding layer 4b configured to directly bond to another reconstituted wafer or substrate. The first bonding layer 4, the contacts 6, and the nonconductive field region 5 of FIGS. 1A-5 have been renumbered as reference numerals 4a, 6a, and 5a, respectively, in FIG. 6. As shown in FIG. 6, in some embodiments, the second bonding layer 4b, e.g., a DBI layer having alternating conductive contacts 6b and nonconductive bonding portions (e.g., field regions 5b), can be provided over the nonconductive layer 18 (e.g., a second oxide layer) to facilitate additional bonding connections, if desired, to provide bonding pads conducive to DBI alignment. Thus, in FIG. 6, the second bonding layer 4b can extend across multiple (e.g., all) of the elements 2 of the reconstituted wafer 20. A horizontal interface 19 can be formed between the second bonding layer 4b and the nonconductive layer 18, and between the second bonding layer 4b and the underlying protective material 7.

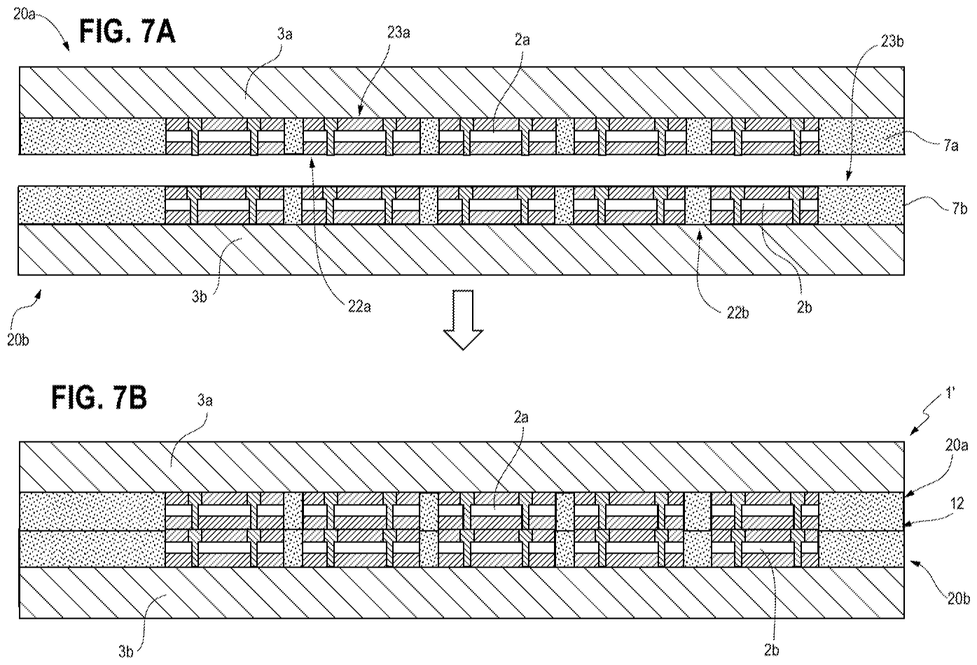

In FIGS. 7A-7B, two opposing reconstituted wafers 20a, 20b can be provided and can be directly bonded to form a pair of bonded reconstituted wafers 1′. The reference numerals have been appended with “a” or “b” to denote their respective associations with the reconstituted wafers 20a or 20b. FIG. 7A illustrates the two opposing reconstituted wafers 20a, 20b prior to direct bonding. FIG. 7B illustrates the two opposing reconstituted wafers 20a, 20b after being directly bonded to one another. Use of direct bonding on the carriers 3a, 3b provides the planarity desired at the die bonding surfaces for die-to-die direct bonding of conductive and non-conductive surfaces. In other embodiments, however, the carriers may not be used and instead the reconstituted wafers may comprise elements (e.g., dies) at least partially embedded in a molding compound or encapsulant without the use of a carrier. In FIG. 7B, the nonconductive protective layers can be directly bonded to one another without an adhesive along the bond interface 12. Other non-conductive field regions of the reconstituted wafers 20a, 20b (such as nonconductive field regions 5a, 5b of bonding layers 4a, 4b, the nonconductive layer(s) 8, etc.) can also be bonded to one another by an adhesive. Moreover, the conductive contacts 6a, 6b can be directly bonded without an adhesive. In some embodiments, some or all of the conductive contacts 6a, 6b can be initially recessed relative to the bonding surfaces. The bonded wafers 20a, 20b can be heated to cause the contacts 6a, 6b to expand and form an electrical contact. After heating, the interface between the contacts 6a and 6b may not be in the same plane as the bond interface 12.

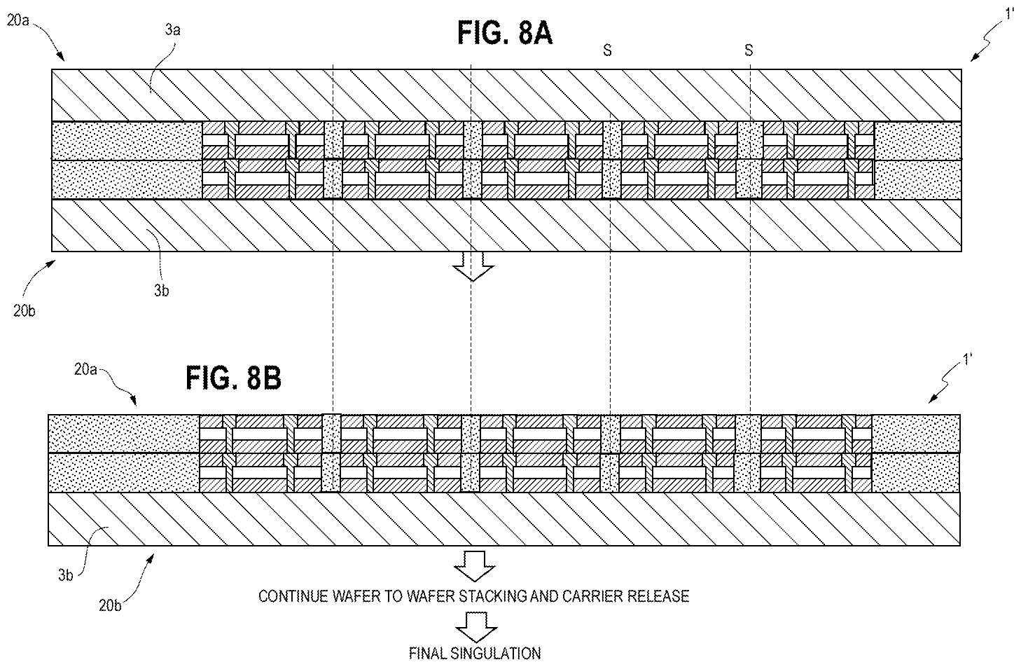

Additional reconstituted wafers 20a, 20b can be provided as shown in FIGS. 8A-8B to provide any number of stacked reconstituted wafers 1′. The stacked reconstituted wafers 1′ can be singulated along singulation streets S to provide a plurality of bonded structures 1. Any suitable number of reconstituted wafers 20a, 20b can be provided to form the stacked reconstituted wafers 1′, which can also be singulated to form any suitable number of bonded structures 1. The singulation can be before removal of the carriers 3 as shown (if sacrificial), or after singulation. In some embodiments, as shown in FIG. 8A, both carriers 3a, 3b may not be removed prior to singulation. In some embodiments, as shown in FIG. 8B, one carrier 3a can be removed prior to singulation. In other embodiments, both carriers 3a, 3b can be removed prior to singulation. As explained herein, removal of the carriers 3a and/or 3b using, for example, an etch process, may leave behind a nano oxide layer 11 to facilitate additional direct bonding.

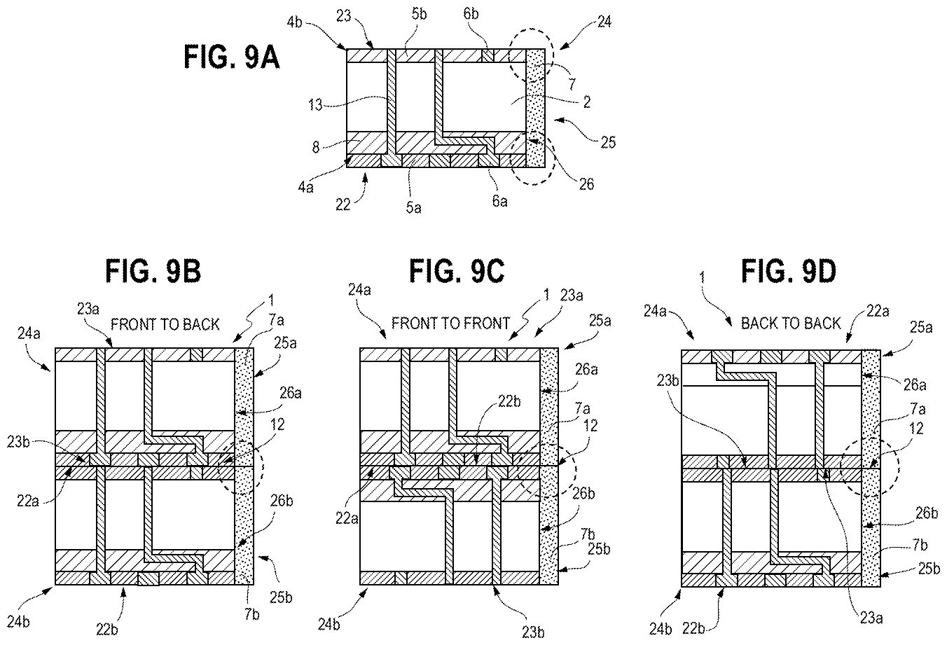

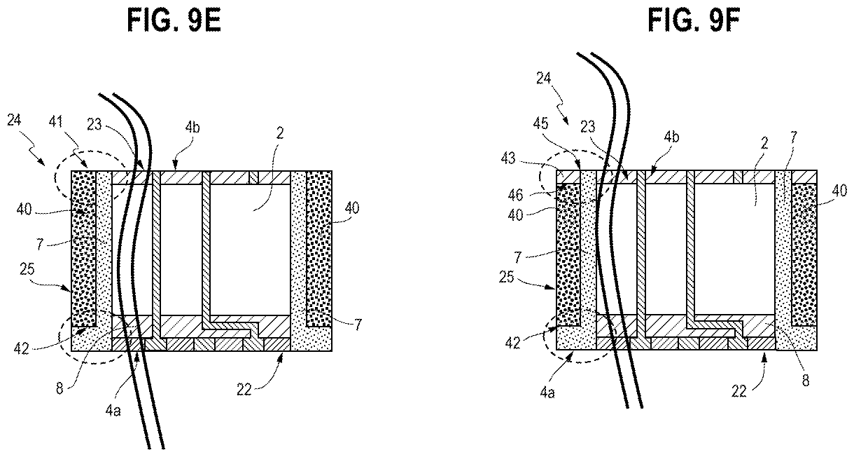

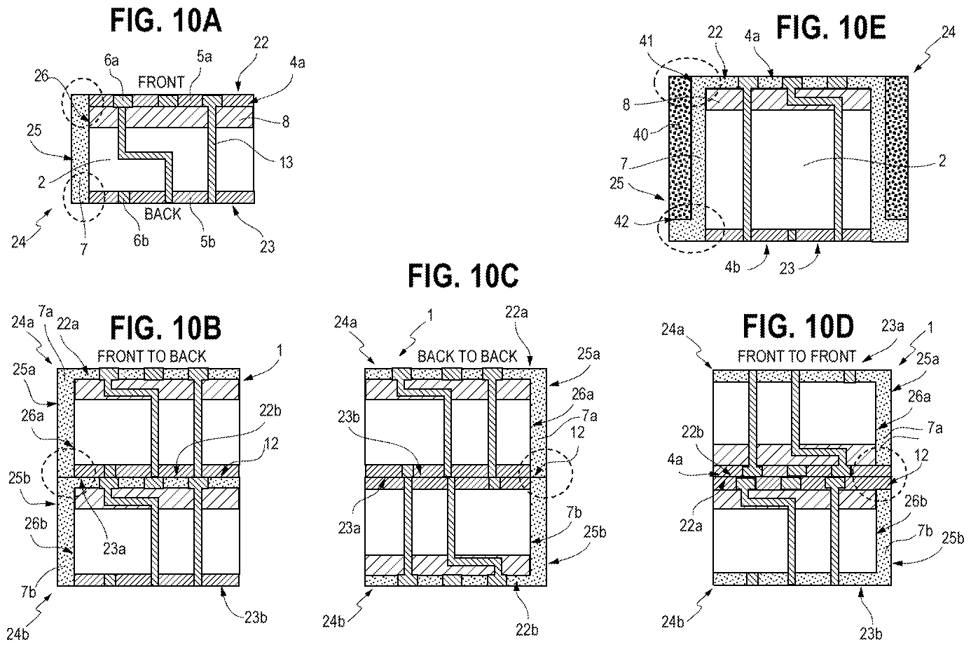

FIGS. 9A-9F and 10A-10E illustrate various face up or face down bonded structures 1 that can result from the methods described herein. The bonded structures 1 shown in FIGS. 9A-9F and 10A-10E can comprise singulated reconstituted elements 24, such as singulated reconstituted integrated device dies. The singulated reconstituted elements 24 are shown in FIGS. 9A, 9E and 9F for illustrative purposes to show what structures may result from a singulated reconstituted wafer 20, according to various embodiments. As shown in FIGS. 9A-9F and 10A-10E, the surfaces nearest to active circuitry or devices can be the front surfaces 22 of the bonded structures 1, while the surfaces opposite the front surfaces 22 can be the back surfaces 23. Unlike individually picked and placed dies or elements, the directly bonded reconstituted elements 24 of the illustrated embodiments can have coplanar side surfaces as well as a direct bonding interface 12 between conductive (e.g., metal) and nonconductive (e.g., inorganic dielectrics such as oxides, including nitrogen and/or fluorine content to aid direct bonding) surfaces of the reconstituted elements 24, with no intervening adhesives.

FIGS. 9A-9F illustrate examples of face down bonded structures. Turning to FIG. 9A, the singulated reconstituted element 24 can comprise the element 2, the nonconductive layer 18 disposed on the thinned back side 10′ of the element 2, and bonding layers 4a, 4b at the front and back surfaces 22, 23, respectively. As shown in FIG. 9A, the protective material 7 can extend from the back side 23 to the front side 22 of the reconstituted element 24. Thus, in the embodiment of FIG. 9A, the singulated reconstituted element 24 can have a sidewall 25 defined by the outer exposed surface of the protective material. A vertical interface 26 can be defined between the protective material 7 and the element 2, the nonconductive layer 8, and the first and second bonding layers 4a, 4b. In the arrangement of FIG. 9A, the protective material 7 accordingly abuts the bonding layers 4a, 4b, which may be applied before the protective material 7 is provided. In other embodiments, as explained in connection with FIG. 6, one or more of the bonding layers 4a, 4b can extend over the protective material 7 such that the sidewall 25 includes the protective material 7 and a side edge of the bonding layers 4a and/or 4b.

FIG. 9B illustrates a front-to-back bonding arrangement in which the front surface 22a of the reconstituted element 24a is directly bonded to the back surface 23b of the reconstituted element 24b without an intervening adhesive to form the bonded structure 1. In FIG. 9B, a first portion 7a of protective material can extend from the back surface 23a of the reconstituted element 24a to the bonding interface 12. A second portion 7b of protective material can extend from the bonding interface 12 to the front surface 22b of the reconstituted element 24b.

FIG. 9C illustrates a front-to-front bonding arrangement in which the front surface 22a of the reconstituted element 24a is directly bonded to the front surface 23a of the reconstituted element 24b without an intervening adhesive to form the bonded structure 1. In FIG. 9C, the first portion 7a of protective material can extend from the back surface 23a of the reconstituted element 24a to the bonding interface 12. The second portion 7b of protective material can extend from the bonding interface 12 to the back surface 23b of the reconstituted element 24b.

FIG. 9D illustrates a back-to-back bonding arrangement in which the back surface 23a of the reconstituted element 24a is directly bonded to the back surface 23b of the reconstituted element 24b without an intervening adhesive to form the bonded structure 1. In FIG. 9D, the first portion 7a of protective material can extend from the front surface 22a of the reconstituted element 24a to the bonding interface 12. The second portion 7b of protective material can extend from the bonding interface 12 to the front surface 22b of the reconstituted element 24b.

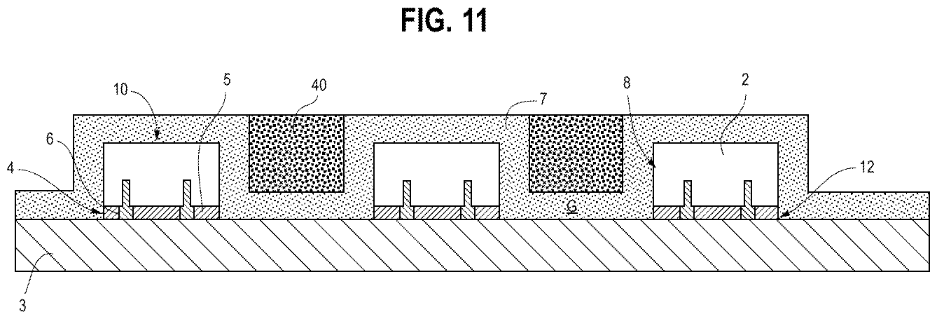

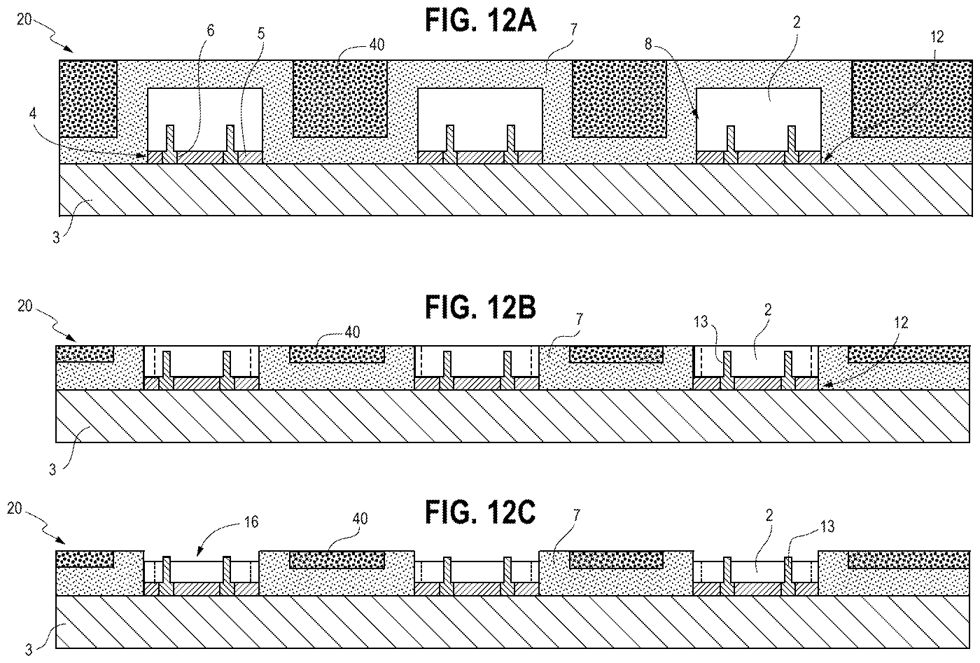

FIGS. 9E and 9F illustrate additional examples of singulated reconstituted elements 24 that utilize a second protective layer 40. Additional details regarding methods of forming the reconstituted element 24 of FIGS. 9E and 9F may be found below in, for example, FIGS. 11-12C. In the embodiment of FIG. 9E, for example, the second protective material 40 can be applied over the protective material 7. In FIG. 9E, the second protective material 40 may be exposed at the back surface 23 of the reconstituted element 24 adjacent the bonding layer 4b. Further, the protective material 7 can be exposed at the front surface 22 adjacent the bonding layer 4a and underlying the second protective layer 40. Thus, in FIG. 9E, the sidewall 25 can include a horizontal interface 42 between the first and second protective materials 7, 25. Moreover, at the back surface 23, a vertical interface 41 can be provided between the first and second protective materials 7, 25.

In the embodiment of FIG. 9F the second protective material 40 can also be applied over the protective material 7. However, unlike the embodiment of FIG. 9E, in FIG. 9F, a third protective layer 43 can be provided over the second protective material 40. The third protective layer 43 may be exposed at the back surface 23 of the reconstituted element 24. Thus, in FIG. 9F, a vertical interface 45 can be provided between the protective material 7 and the third protective material 43. A horizontal interface 46 can be provided between the second protective material 40 and the third protective material 43.

FIGS. 10A-10E illustrate examples of face up bonded structures 1. Unless otherwise noted, reference numerals in FIGS. 10A-10E may refer to the same or generally similar components as reference numerals in FIGS. 9A-9F. Turning to FIG. 10A, a singulated reconstituted element 24 is shown in a face up orientation. In FIGS. 10B-10D, respective reconstituted elements 24a, 24b are directly bonded to one another to form bonded structures.

As with FIG. 9B, FIG. 10B illustrates a front-to-back bonding arrangement in which the front surface 22a of the reconstituted element 24a is directly bonded to the back surface 23b of the reconstituted element 24b without an intervening adhesive to form the bonded structure 1. In FIG. 10B, a first portion 7a of protective material can extend from the back surface 23a of the reconstituted element 24a to the bonding interface 12. A second portion 7b of protective material can extend from the bonding interface 12 to the front surface 22b of the reconstituted element 24b.

FIG. 10C illustrates a back-to-back bonding arrangement in which the back surface 23a of the reconstituted element 24a is directly bonded to the back surface 23b of the reconstituted element 24b without an intervening adhesive to form the bonded structure 1. In FIG. 10C, the first portion 7a of protective material can extend from the front surface 22a of the reconstituted element 24a to the bonding interface 12. The second portion 7b of protective material can extend from the bonding interface 12 to the front surface 22b of the reconstituted element 24b.

FIG. 10D illustrates a front-to-front bonding arrangement in which the front surface 22a of the reconstituted element 24a is directly bonded to the front surface 22b of the reconstituted element 24b without an intervening adhesive to form the bonded structure 1. In FIG. 10D, the first portion 7a of protective material can extend from the back surface 23a of the reconstituted element 24a to the bonding interface 12. The second portion 7b of protective material can extend from the bonding interface 12 to the back surface 23b of the reconstituted element 24b. In FIG. 10D, the bonding layers 4a can extend over the protective material 7a, 7b and can be exposed on the sidewall 25. As explained above in connection with FIG. 6, in some embodiments, the bonding layer 4a can be provided across the wafer over the protective material 7 such that, when the reconstituted wafer is singulated, the bonding layer 4a is exposed at the sidewall and flush with the protective material 7 at the sidewall 25.

FIG. 10E illustrates a singulated reconstituted element 24 that has a second protective material 40 disposed over side and upper surfaces of the protective material 7. Unlike the embodiment of FIGS. 9E and 9F, in FIG. 10E, the first front bonding layer 4a can be coplanar or flush with the second protective material 40. The second back bonding layer 4b can be coplanar or flush with the protective material 7.

FIG. 11 illustrates another embodiment similar to those described above, except an additional filler material can serve as a second protective material 40 and may be provided over a conformal protective material 7 in the gaps G between adjacent elements 2. The protective material 7 can be deposited conformally over the back sides 10 and side surface 8 of the elements 2 and over the upper surface of the carrier 3. The conformal protective material 7 can have gaps G between portions of the protective material 7 disposed on the side surfaces 8 of the elements 2. The second protective material 40 can serve to fill the gaps G. The second filler protective material 40 can comprise any suitable material, including organic or inorganic materials.

FIGS. 12A-12C illustrate a method for forming a reconstituted wafer 20 according to various embodiments. FIG. 12A is generally similar to FIG. 11, except additional portions of the second protective material 40 are provided on the ends of the outer elements 2. In FIG. 12B, a portion of the protective material 7 and a portion of the second filler protective material 40 can be removed to provide a generally planar surface. In various embodiments, for example, the respective portions of the filler and conformal protective materials 40, 7 can be removed by etching, lapping, grinding, chemical mechanical polishing (CMP), etc. In FIG. 12C, a portion of the bulk semiconductor material of the elements 2 or dies (e.g., silicon) can be removed to form a cavity 16, for example, by etching, lapping, CMP, etc., to expose the conductive vias 13. The conformal and/or gap-fill protective materials may have coefficient(s) of thermal expansion that is (are) within 5 ppm/° C. of a coefficient of thermal expansion of the elements 2 (e.g., integrated device dies).

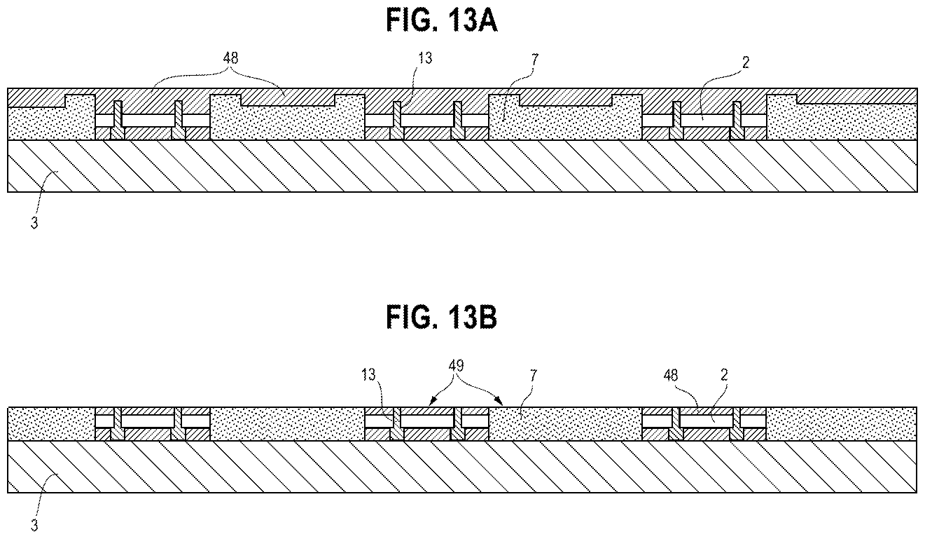

In FIG. 13A, the second filler protective material 40 can be removed from the structure shown in FIG. 12C, and an additional protective material 48 can be provided over the elements 2 and the exposed vias 13. In FIG. 13B, the provided additional protective material 48 and a portion of the protective material 7 can be removed or planarized to form a bonding surface 49 with the vias exposed on the upper surface.

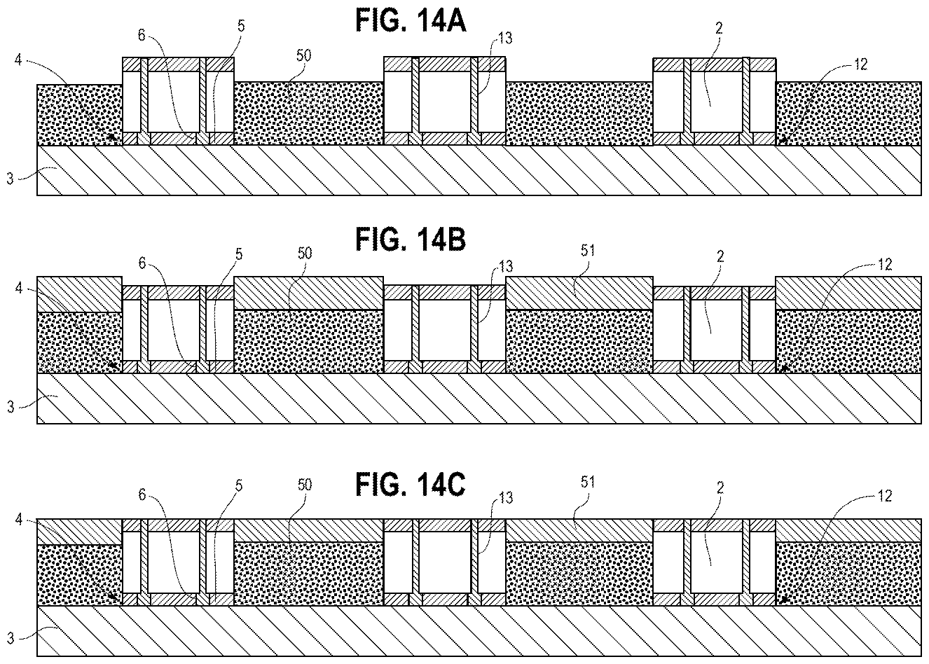

FIGS. 14A-14C illustrate another embodiment in which a mold compound 50 can be provided between adjacent elements 2 directly bonded to a carrier 3 without an adhesive. In FIG. 14A, the vias 13 are shown as being exposed on the back side, but in other embodiments, the vias 13 can be buried as illustrated above. As shown in FIG. 14B, a metal 51 (such as copper) can be provided over the mold compound 51 as shown in FIG. 14B. For example, in various embodiments, the metal 51 can be provided using an electroless plating process, a sputtering process, or any other suitable method. As shown in FIG. 14C, the metal 51 can be planarized, for example, by chemical mechanical polishing (CMP), or any other suitable method. In some embodiments, structures that utilize an organic material for the mold compound may be challenging to planarize using CMP to sufficient smoothness (e.g., less than 5 nm, etc.). By providing a metal 51 (such as copper) over the mold compound, CMP or other planarization processes can be used to planarize to sufficient smoothness for direct bonding.

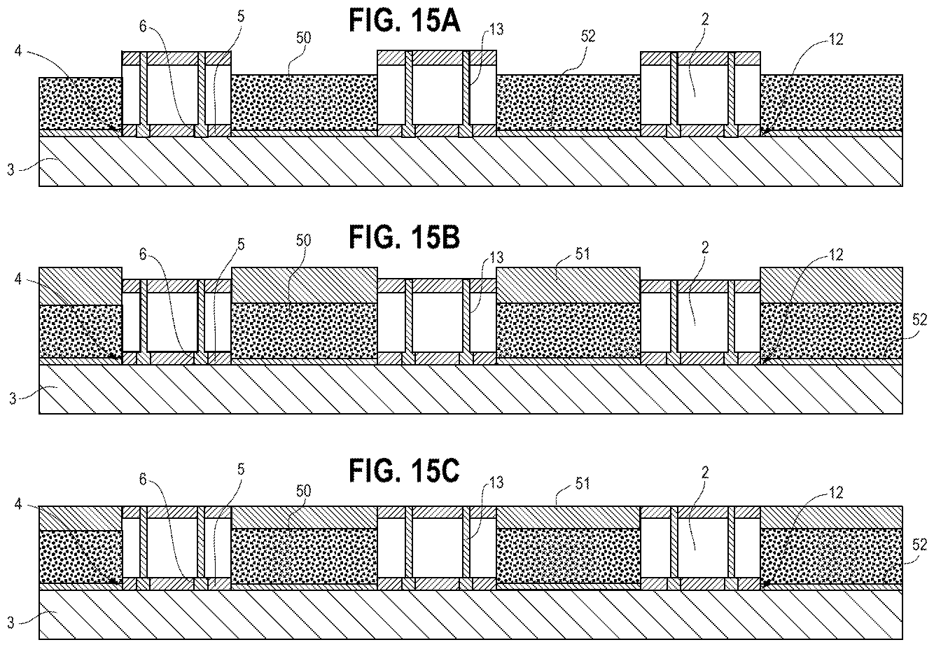

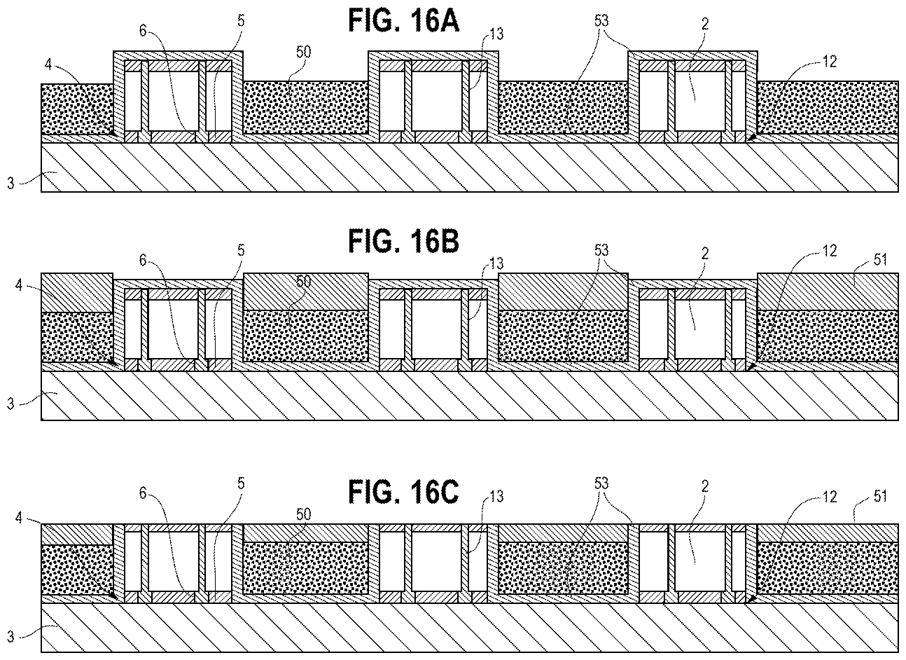

FIGS. 15A-15C are generally similar to FIGS. 14A-14C, except in FIGS. 15A-15C, a second metal 52 can be provided over the carrier 3 between the carrier 3 and the mold compound 50. FIGS. 16A-16C illustrate another embodiment in which a protective coating 53 or layer (e.g., silicon oxide) can be provided between the mold compound 50 and the carrier 3. A protective coating can also be provided after die placement and before metal deposition in various embodiments. In FIG. 16A, the protective coating 53 can conformally coat the upper surface of the carrier 3 and upper and side surfaces of the elements 3. The mold compound 50 can be provided over the protective coating 53 and between the elements 2. In FIG. 16B, the metal 51 can be provided over the mold compound 50 as explained above. In FIG. 16C, the portions of the protective coating 53 that overlie the elements 2 can be removed using a polishing, grinding, or lapping process to expose the vias 13. The metal 51 and element 2 can be planarized to form a smooth surface for bonding.

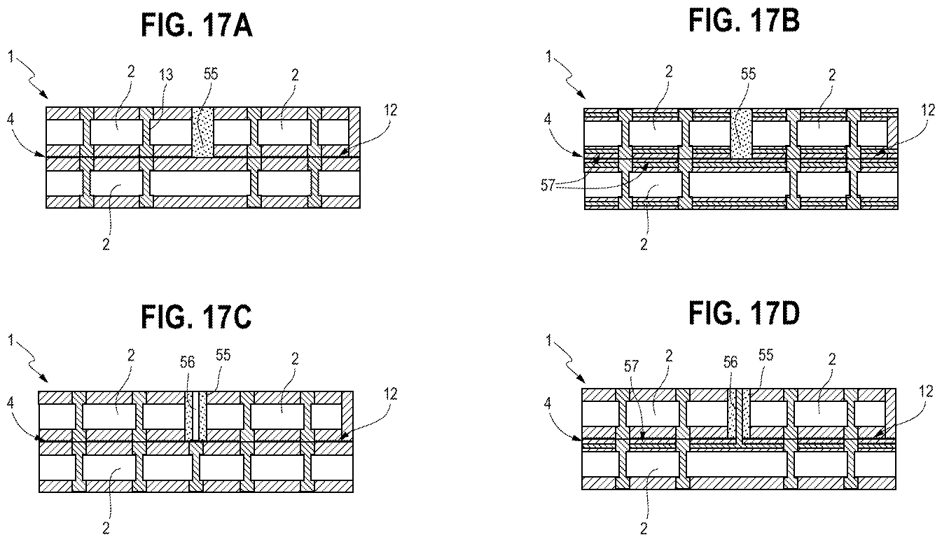

FIGS. 17A-17D illustrates additional bonded structures 1 that can be provided with the methods disclosed herein. In FIG. 17A, the bonded structure 1 can include a plurality of elements 2, which can include combinations of integrated device dies and interposers. Thus, the methods disclosed herein can be used for active and/or inactive devices. Moreover, as shown in FIG. 17A, an insulating column 55 can be provided to separate the adjacent elements 2 in the upper reconstituted element. In FIG. 17B, the bonded structure 1 can include one or more redistribution layers (RDLs) 57 which can include lateral conductive routing traces to carry signals laterally inward or outward. The RDLs 57 can enable fan-in or fan-out arrangements for connecting to an external package substrate. In FIG. 17C, a conductive via 56 can be provided in the insulating column 56 to carry signals from the lower element 2 to the upper surface of the bonded structure 1. In FIG. 17D, the bonded structure 1 can include both the via 56 in the insulating column 56 and the RDL(s) 57. Skilled artisans will understand that additional combinations may be suitable.

### Additional Examples of Integrated Device Packages

Integrated device packages can include one or multiple integrated device dies (e.g., chips) that have active circuitry, such as transistors and other types of active devices. The integrated device dies can be mounted to a carrier, such as a semiconductor interposer, a semiconductor or dielectric (e.g., glass) substrate, another integrated device die, a reconstituted wafer or element, etc. In various arrangements, a molding compound or encapsulant can be provided over the integrated device dies and exposed surfaces of the package substrate. The molding compound can comprise a polymer material, such as an epoxy or potting compound. The material of the molding compound can have a coefficient of thermal expansion (CTE) that differs from the CTE of the carrier and/or of the integrated device die(s). During process steps at elevated temperatures, the CTE mismatch between the molding compound and the carrier (and/or integrated device die(s)) may induce stresses in the carrier and/or integrated device die(s). For example, the stresses induced by CTE mismatch can cause cracking and/or warpage of the carrier and/or integrated device die(s), which can reduce package yield and/or affect system performance. Accordingly, there remains a continuing need for improved packages that reduce stresses due to CTE mismatch between molding compound and the carrier (and/or integrated device die(s)).

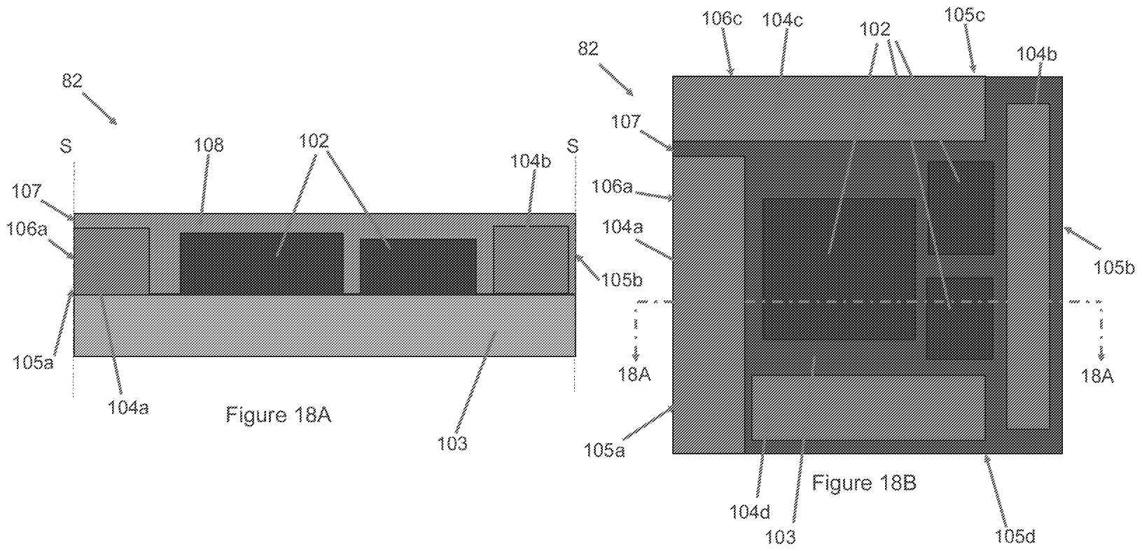

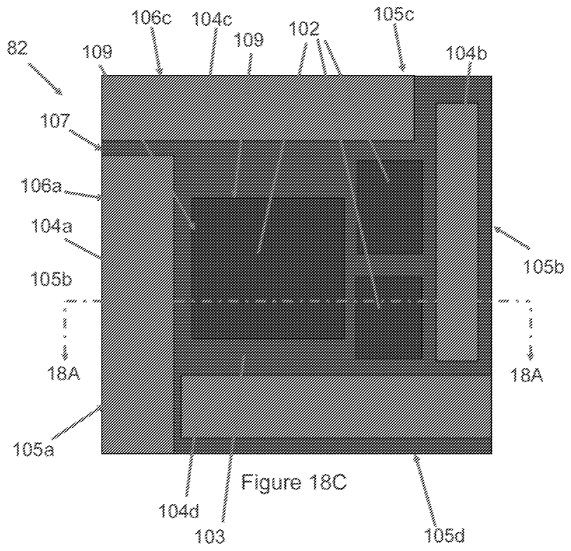

FIG. 18A is a schematic side sectional view of an integrated device package 82, according to various embodiments. FIG. 18B is a schematic top plan view of the integrated device package 82 of FIG. 18A. As shown in FIGS. 18A-18B, the package 82 can comprise a carrier 103 and a plurality of integrated device dies 102 mounted to an upper surface of the carrier 103. The integrated device dies 102 can comprise active circuitry. For example, the integrated device dies 102 can comprise processor die(s), memory die(s), sensor die(s), microelectromechanical systems (MEMS) dies, or any other suitable device that includes active circuitry (such as transistors or other active devices). Three integrated device dies 102 are shown in the top view of FIG. 18B, but it should be appreciated that any suitable number of device dies 102 can be provided. For example, one or two integrated device dies 102 can be mounted to the carrier 103, or more than three integrated device dies 102 can be mounted to the carrier. Further, in FIGS. 18A-18B, the integrated device dies 102 are spaced apart laterally along the carrier 103. Alternatively or additionally, integrated device dies 102 can be stacked vertically in order to reduce package footprint.

The carrier 103 can comprise any suitable support structure for the integrated device dies 102. For example, in some embodiments, the carrier 103 can comprise an interposer (such as a semiconductor interposer), a semiconductor or dielectric (e.g., glass) substrate, another integrated device die (e.g., an active chip with active electronic circuitry), a reconstituted wafer or element, etc. The carrier 103 can comprise a material (e.g., a semiconductor material, a dielectric material, etc.) having a first CTE. In various embodiments, the integrated device dies 102 can have a CTE that is substantially similar to the first CTE of the carrier 103. In some embodiments, bulk material of one or more of the dies 102 may be the same material as corresponding bulk material of the carrier 103. In various embodiments, the carrier 103 can comprise silicon, glass, or any other suitable material. In some embodiments, the carrier 103 can comprise an integrated device die (such as a processor die) that has a larger lateral footprint than the dies 102. The integrated device dies 102 can be mounted to the carrier 103 in any suitable manner. For example, the dies 102 can be directly hybrid bonded to the carrier 103 without an adhesive, as explained herein. In such embodiments, nonconductive field regions of the dies 102 can be directly bonded to corresponding nonconductive field regions of the carrier 103 without an adhesive. Moreover, conductive contacts of the dies 102 can be directly bonded to corresponding conductive contacts of the carrier 103 without an adhesive. In other embodiments, however, the dies 102 can be mounted to the carrier 103 with an adhesive. In some embodiments, the carrier 103 can remain coupled to the dies 102 such that the carrier 103 remains present in the larger electronic system. In still other embodiments, the carrier 103 can comprise a temporary structure (such as a mounting tape or sacrificial substrate) that is removed (e.g., lifted off or etched away) and not present in the final electronic package or system.

As shown in FIG. 18A, a molding compound 108 can be provided over the integrated device dies 102 and over an exposed upper surface of the carrier 103. The molding compound 108 is hidden in the top view of FIG. 18B for case of illustration. The integrated device dies 102 can be at least partially embedded (e.g., completely embedded or buried) within the molding compound 108. As explained above, the molding compound 108 can comprise a polymer material (such as an epoxy or potting compound) that has a second CTE that is different from the first CTE of the carrier 103 (and/or of the dies 102). For example, the second CTE of the molding compound 108 can differ from the first CTE of the carrier 103 (and/or of the dies 102) by an amount that is sufficiently large so as cause CTE-induced stresses on the carrier 103 and/or dies 102 (e.g., the CTE mismatch can be up to about 12 ppm in some cases). As explained above, during process steps at elevated temperatures, the CTE mismatch between the molding compound 108 and the carrier 103 (and/or dies 102) can induce stresses that cause warpage, cracks, or other types of damage to the components of the package 82.

To reduce the effects of CTE mismatch between the molding compound 108 and the carrier 103 (and/or dies 102), the package 82 can include one or a plurality of stress compensation elements 104a-104d mounted to the upper surface of the carrier 103. As shown, the stress compensation elements 104a-104d can be disposed around the integrated device dies 102, such that the integrated device dies 102 are disposed within an interior region of the package 82 surrounded by the stress compensation elements 104a-104d. The molding compound 108 can also be provided or applied over the stress compensation elements 104a-104d, such that the stress compensation elements 104a-104d are at least partially embedded in the molding compound 108. The stress compensation elements 104a-104d can be spaced apart from one another and from the dies 102 by intervening portions of the molding compound 108. The stress compensation elements 104a-104d can comprise a semiconductor material (e.g., silicon), an insulating material (e.g., glass), or any other suitable material type that has a CTE that substantially matches (or is close to) the second CTE of the carrier 103 and/or the dies 102. In some embodiments, the stress compensation elements 104a-104d can comprise the same material as the carrier 103 and/or the dies 102. In other embodiments, the stress compensation elements 104a-104d can comprise a material that is different from that of the carrier 103 and/or the dies 102. Each stress compensation element 104a-104d can comprise the same material, or some (or all) can comprise different materials. In various embodiments, the CTE of the stress compensation elements 104a-104d can be within 10% of the second CTE of the carrier 103 and/or of the integrated device dies 102, within 5% of the second CTE, or within 1% of the second CTE. In various embodiments, the CTE of the stress compensation elements 104a-104d can be less than 10 ppm, less than 8 ppm, or less than 7 ppm. For example, the CTE of the stress compensation elements 104a-104d can be in a range of 3 ppm to 7 ppm.

Beneficially, the stress compensation elements 104a--104d can reduce the stresses imparted to the carrier 103 and/or the dies 102, since the material composition of the stress compensation elements 104a-104d is selected to have a CTE that substantially matches that of the carrier 103 and/or the dies 102. The CTE-matched stress compensation elements 104a-104d can be provided over a large area of the carrier 103 so as to serve as a stress-matched filler that compensates or reduces any stresses induced by the CTE mismatch between the molding compound 108 and the carrier 103 and/or dies 102. For example, in some embodiments, the stress compensation elements 104a-104d can be mounted so as to cover most of an unoccupied area of the carrier 103 (e.g., regions of the carrier 103 that do not support the dies 102 or other electronic components or devices), e.g., at least 20%, at least 50%, at least 75%, at least 85%, or at least 90% of the unoccupied area of the carrier 103. In some embodiments, the stress compensation elements 104a-104d can be mounted so as to cover a range of 20% to 90% of the unoccupied area of the carrier 103, a range of 35% to 90% of the unoccupied area of the carrier 103, or a range of 50% to 90% of the unoccupied area of the carrier 103. In some embodiments, as shown in the top view of FIG. 18B, the stress compensation elements 104a-104d can laterally overlap such that all lines perpendicular to opposing side edges 105a, 105b can pass through or intersect at least one stress compensation element 104a-104d. In such arrangements, the stress compensation elements 104a-104d can serve to prevent or arrest cracks from propagating through the carrier 103.

Further, as shown in the top plan view of FIG. 18B, the stress compensation elements 104a-104d can be disposed between the outer side edges 105a-105d of the package 82 and the integrated device dies 102 such that at least one lateral side edge 109 of each integrated device die 102 lies in a corresponding plane that intersects at least one stress compensation element 104a-104d. In some embodiments, a majority (or all) of the side edges 109 of the dies 102 can lie in respective planes that intersect at least one stress compensation element 104a-104d.

FIG. 18C is a schematic top plan view of an integrated device package 82, that includes increased lateral overlap among the stress compensation elements 104a-104d. Unless otherwise noted, the components of FIG. 18C may be the same as or generally similar to like-numbered components of FIGS. 18A-18B. In FIG. 18C, stress compensation element 104b is vertically (as shown in the top view) shortened, and stress compensation element 104d is horizontally (as shown in the top view) lengthened as compared to FIG. 18B. Thus, in FIG. 18C, stress compensation element 104d can extend to and be exposed along side edge 105b. In FIG. 18C, all lines perpendicular to each side edge 105a-105d can pass through or intersect with at least one stress compensation element 104a-104d, which can prevent or arrest crack propagation.

In some embodiments, the stress compensation elements 104a-104d can comprise dummy stress compensation elements that are devoid of active circuitry, e.g., there are no active devices in the dummy stress compensation elements. In such embodiments, the dummy stress compensation elements can comprise dummy pieces or blocks of a semiconductor material (such as silicon) or a dielectric material (such as glass) without any active circuitry. The use of dummy elements can provide further benefits because no circuitry or devices need be patterned or formed in the elements 104a-104d, which can reduce processing costs and complexity. However, in other embodiments, one or more of the stress compensation elements 104a-104d may comprise an active integrated device die with active circuitry or devices. The use of multiple stress compensation elements 104a-104d can beneficially enable the package assembler to pick and place the elements 104a-104d at desired locations, e.g., at locations with high susceptibility to cracking and/or in targeted spaces over the carrier 103.

As with the integrated device dies 102, the stress compensation elements 104a-104d can be mounted to the carrier 103 in any suitable manner. For example, the stress compensation elements 104a-104d can be directly bonded to the carrier 103 without an adhesive. As explained above, the stress compensation elements 104a-104d can comprise dummy stress compensation elements without active circuitry. In such embodiments, the stress compensation elements 104a-104d can comprise nonconductive field regions that are directly bonded to corresponding nonconductive field regions of the carrier 103 along a bond interface without an adhesive. Further, in some embodiments, the stress compensation elements 104a-104d may be directly bonded such that the bond interface between the elements 104a-104d and the carrier 103 includes only nonconductive-to-nonconductive direct bonds (e.g., the bond interface is devoid of conductor-to-conductor or metal-to-metal direct bonds). For example, in embodiments that utilize dummy stress compensation elements without active circuitry and/or contact pads, the stress compensation elements 104a-104d can be directly bonded to the carrier 103 utilizing only nonconductive-to-nonconductive direct bonds, e.g., a nonconductive or dielectric bonding layer of the elements 104a-104d can be directly bonded to a corresponding nonconductive or dielectric bonding layer of the carrier 103 without an adheisve. In such embodiments, the nonconductive-to-nonconductive direct bonds can comprise one type or multiple different types of nonconductive material(s) along the bond interface. Thus, in various embodiments disclosed herein, one or more elements (such as dies 102) can be hybrid direct bonded to the carrier 103 along a bond interface without an adhesive such that nonconductive field regions and conductive contact pads of the one or more elements (e.g., dies 102) are directly bonded to corresponding nonconductive field regions and conductive contacts of the carrier 103. One or more other elements (such as stress compensation elements 104a-104d) can be directly bonded to the carrier 103 without an adhesive along the bond interface such that the bond interface between the stress compensation elements 104a-104d and the carrier 103 includes only nonconductive-to-nonconductive direct bonds (e.g., directly bonded dielectric bonding layers of the elements 104a-104d and carrier 103). For example, some elements 104a-104d may not include any conductive contacts that are directly bonded to the carrier 103. The nonconductive field regions of the dies 102, stress compensation elements 104a-104d, and/or carrier 103 can comprise an inorganic dielectric material (e.g., silicon oxide). The nonconductive field regions can comprise unpatterned portions of the dies 102, stress compensation elements 104a-104d, and/or carrier 103. The bond interface can include signature indicative of direct nonconductive bonds, such as nitrogen terminated surfaces, fluorine peak(s) at the bond interface and at upper and/or lower interfaces of dielectric bonding layers of the elements.

In other embodiments, such as those in which the stress compensation elements 104a-104d comprise circuitry and contact pads, both nonconductive field regions and contact pads of the stress compensation elements 104a-104d can be directly bonded to corresponding nonconductive field regions and contact pads of the carrier 103. In still other embodiments, the stress compensation elements 104a-104d can be bonded to the carrier 103 with an adhesive. In some embodiments, the carrier 103 can be mounted to an external device, such as a system motherboard, or to another structure. In other embodiments, the carrier 103 can comprise a temporary support structure that can be removed after the molding compound 108 is applied. Four stress compensation elements 104a-104d are shown in FIG. 18B, but it should be appreciated that fewer than four, or more than four, stress compensation elements 104a-104d can be provided.

As shown in FIGS. 18A-18B, the package 82 can comprise outer side edges 105a-105d. The package 82 can be formed from a singulation process by which a larger wafer or reconstituted wafer is singulated along singulation streets S to yield a plurality of singulated packages 82. In some embodiments, singulation can comprise a sawing process, an etching process, or any other suitable process by which packages 82 can be formed from a larger wafer or reconstituted wafer. After singulation, the outer side edges 105a-105d (including, e.g., outer edges of the stress compensation elements 104a, 104c, the carrier 103, and/or the molding compound 108 as shown in FIG. 18B) can comprise singulation markings indicative of the singulation process. For example, for saw singulation processes, the singulation markings can comprise saw markings, such as striations in the singulated surface. For etch singulation processes, the singulation markings can comprise marks or microstructures indicative of the etch pathway. In the embodiment of FIG. 18C, the outer side edge 105b can include an outer edge of stress compensation element 104d, an edge of the carrier 103 and the molding compound, each of which may include markings indicative of the singulation process. It should be appreciated that the stress compensation elements 104a-104d can be positioned anywhere along the carrier 103. For example, in other embodiments, some or all of the stress compensation elements 104a-104d can be positioned laterally inset relative to the outer side edges 105a-105d of the package 82 such that the stress compensation elements 104a-104d are embedded in the molding compound 108.

In various embodiments, the singulation streets S can pass through one or more of the stress compensation elements 104a-104d such that, upon singulation, the molding compound 108 and one or more stress compensation elements 104a-104d can be exposed along one or more outer side edges 105a-105d of the package 82. For example, as shown in FIGS. 18A-18B, stress compensation elements 104a, 104c can comprise side edges 106a, 106c that are exposed at the corresponding outer side edges 105a, 105c of the package 82. In addition, side edges 107 of the molding compound 108 can be exposed along the outer side edges 105a-105d of the package 82. As shown, the exposed side edges 106a, 106c of the stress compensation elements 104a, 104c can be flush with the side edges 107 of the molding compound 108, including portions of the molding compound 108 that are over the stress compensation elements 104a, 104c and portions of the molding compound 108 that are laterally adjacent the stress compensation elements 104a, 104c. In various embodiments, some stress compensation elements 104b, 104d can be laterally inset relative to the outer side edges 105b, 105d of the package 82, such that the elements 104b, 104d may be completely embedded in the molding compound 108. In some embodiments, all of the stress compensation elements 104a-104d can be laterally inset relative to the outer side edges 105a-105d.

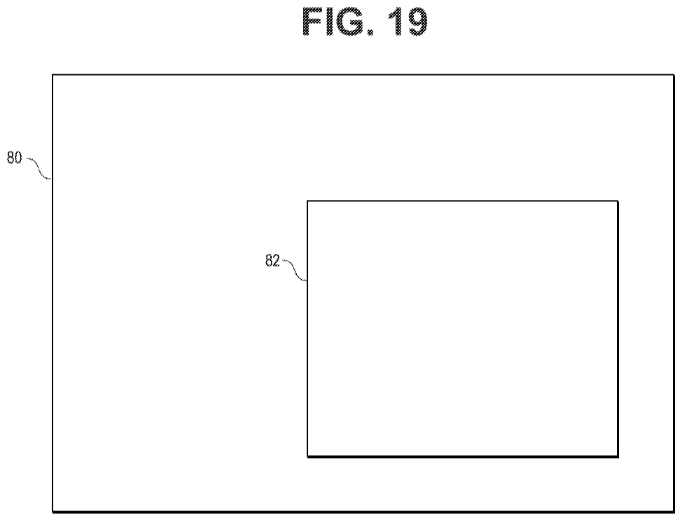

FIG. 19 is a schematic diagram of a system 80 incorporating one or more integrated device packages 82, according to various embodiments. The system 80 can comprise any suitable type of electronic device, such as a mobile electronic device (e.g., a smartphone, a tablet computing device, a laptop computer, etc.), a desktop computer, an automobile or components thereof, a stereo system, a medical device, a camera, or any other suitable type of system. In some embodiments, the electronic device can comprise a microprocessor, a graphics processor, an electronic recording device, or digital memory. The system 80 can include one or more device packages 82 which are mechanically and electrically connected to the system 80, e.g., by way of one or more motherboards. Each package 82 can comprise one or more integrated device dies and/or bonded structures 1. The integrated device dies and/or bonded structures can comprise any of the integrated device packages and/or bonded structures shown and described above in connection with FIGS. 1A-18B.

In one embodiment, an integrated device package is disclosed. The integrated device package can comprise a carrier an a molding compound over a portion of an upper surface of the carrier. The integrated device package can comprise an integrated device die mounted to the carrier and at least partially embedded in the molding compound, the integrated device die comprising active circuitry. The integrated device package can comprise a stress compensation element mounted to the carrier and at least partially embedded in the molding compound, the stress compensation element spaced apart from the integrated device die, the stress compensation element comprising a dummy stress compensation element devoid of active circuitry. At least one of the stress compensation element and the integrated device die can be directly bonded to the carrier without an adhesive.

In another embodiment, an integrated device package is disclosed. The integrated device package can include a molding compound and an integrated device die at least partially embedded in the molding compound, the integrated device die comprising active circuitry. The integrated device package can include a plurality of dummy stress compensation elements at least partially embedded in the molding compound, the plurality of dummy stress compensation elements devoid of active circuitry, the plurality of dummy stress compensation element spaced apart from one another by the molding compound.

In another embodiment, a method of forming an integrated device package is disclosed. The method can include providing a molding compound over an integrated device die and a plurality of dummy stress compensation elements, the plurality of dummy stress compensation elements spaced apart from one another by the molding compound. The integrated device die can comprise active circuitry. The plurality of dummy stress compensation elements can be devoid of active circuitry.

In another embodiment, an integrated device package is disclosed. The integrated device package can comprise a molding compound and an integrated device die at least partially embedded in the molding compound, the integrated device die comprising active circuitry. The integrated device package can comprise a stress compensation element at least partially embedded in the molding compound and spaced apart from the integrated device die. The molding compound and the stress compensation element can be exposed at an outer side edge of the integrated device package.

In another embodiment, an electronic component is disclosed. The electronic component can comprise a carrier having a first nonconductive field region and a first conductive contact. The electronic component can comprise a first element directly hybrid bonded to the carrier without an adhesive, a second nonconductive field region of the first element directly bonded to the first nonconductive field region of the carrier without an adhesive and a second conductive contact of the first element directly bonded to the first conductive contact of the carrier. The electronic component can comprise a second element directly bonded to the carrier without an adhesive such that only a third nonconductive field region of the second element is directly bonded to the first nonconductive field region of the carrier.

In another embodiment, an electronic component is disclosed. The electronic component can include a carrier having a first nonconductive field region and a first conductive contact. The electronic component can include a first element directly hybrid bonded to the carrier without an adhesive, a second nonconductive field region of the first element directly bonded to the first nonconductive field region of the carrier without an adhesive and a second conductive contact of the first element directly bonded to the first conductive contact of the carrier. The electronic component can include a second element directly bonded to the carrier without an adhesive, wherein the second element does not include any conductive contacts that are directly bonded to the carrier.

In one embodiment, a bonded structure is disclosed. The bonded structure can include a first reconstituted element comprising a first element and having a first side comprising a first bonding surface and a second side opposite the first side. The first reconstituted element can comprise a first protective material disposed about a first sidewall surface of the first element. The bonded structure can comprise a second reconstituted element comprising a second element and having a first side comprising a second bonding surface and a second side opposite the first side. The first reconstituted element can comprise a second protective material disposed about a second sidewall surface of the second element. The second bonding surface of the first side of the second reconstituted element can be directly bonded to the first bonding surface of the first side of the first reconstituted element without an intervening adhesive along a bonding interface. The first protective material can be flush with the first bonding surface and the second protective material can be flush with the second bonding surface.

In another embodiment, a bonded structure is disclosed. The bonded structure can include a first reconstituted element comprising a first element and having a first side and a second side opposite the first side. The bonded structure can include a second reconstituted element comprising a second element and having a first side and a second side opposite the first side, the first side of the second reconstituted element directly bonded to the first side of the first reconstituted element without an intervening adhesive along a bonding interface. The bonded structure can include a protective material disposed about respective first and second side surfaces of the first and second elements. The bonded structure can include a nonconductive layer disposed between the first and second elements, the nonconductive layer flush with at least one of the first and second side surfaces of the first and second elements such that an interface is provided between the protective material and the nonconductive layer.

In another embodiment, a bonded structure is disclosed. The bonded structure can include a first reconstituted wafer comprising a plurality of first elements. The bonded structure can comprise a second reconstituted wafer comprising a plurality of second elements. The first and second reconstituted wafers can be directly bonded to one another without an adhesive.

In another embodiment, a bonding method is disclosed. The bonding method can include applying a first protective material over a plurality of first elements to form a first reconstituted wafer. The bonding method can include applying a second protective material over a plurality of second elements to form a second reconstituted wafer. The bonding method can include directly bonding the first reconstituted wafer to the second reconstituted wafer without an adhesive.

In another embodiment, a bonding method is disclosed. The bonding method can include directly bonding a first element to a carrier without an adhesive. The carrier can comprise a silicon carrier with a silicon oxide layer disposed directly onto a surface of the silicon carrier. The silicon oxide layer can be directly bonded to the first element. The silicon oxide layer can comprise a native oxide layer or a thermal oxide layer.

All of these embodiments are intended to be within the scope of this disclosure. These and other embodiments will become readily apparent to those skilled in the art from the following detailed description of the embodiments having reference to the attached figures, the claims not being limited to any particular embodiment(s) disclosed. Although this certain embodiments and examples have been disclosed herein, it will be understood by those skilled in the art that the disclosed implementations extend beyond the specifically disclosed embodiments to other alternative embodiments and/or uses and obvious modifications and equivalents thereof. In addition, while several variations have been shown and described in detail, other modifications will be readily apparent to those of skill in the art based upon this disclosure. It is also contemplated that various combinations or sub-combinations of the specific features and aspects of the embodiments may be made and still fall within the scope. It should be understood that various features and aspects of the disclosed embodiments can be combined with, or substituted for, one another in order to form varying modes of the disclosed implementations. Thus, it is intended that the scope of the subject matter herein disclosed should not be limited by the particular disclosed embodiments described above, but should be determined only by a fair reading of the claims that follow.

What is claimed is:

1. An integrated device package:
a carrier;
a molding compound over a portion of an upper surface of the carrier;
an integrated device die mounted to the carrier and at least partially embedded in the molding compound, the integrated device die comprising active circuitry; and
a stress compensation element mounted to the carrier and at least partially embedded in the molding compound, the stress compensation element spaced apart from the integrated device die, the stress compensation element comprising a dummy stress compensation element devoid of active circuitry,
wherein at least one of the stress compensation element and the integrated device die are directly bonded to the carrier without an adhesive.
